(19) United States
(12) Patent Application Publication
(10) Pub. No.: US 2024/0194693 A1
(43) Pub. Date: Jun. 13, 2024

(54) WIRING STRUCTURE OF TRANSISTOR FOR DRIVING A DISPLAY PANEL AND A DISPLAY DRIVER IC INCLUDING THE SAME

(71) Applicant: LX SEMICON CO., LTD., Daejeon (KR)

(72) Inventor: Cheongsik YU, Daejeon (KR)

(73) Assignee: LX SEMICON CO., LTD., Daejeon (KR)

(21) Appl. No.: 18/532,449

(22) Filed: Dec. 7, 2023

(30) Foreign Application Priority Data
Dec. 7, 2022 (KR) 10-2022-0169613
Nov. 29, 2023 (KR) 10-2023-0170105

(51) Int. Cl. H01L 27/12

(52) U.S. Cl. CPC H01L 27/124

(57) ABSTRACT

The embodiment relates to a wiring structure of a transistor for driving a display panel, a method of manufacturing the same, and a display driver IC including the same.

The wiring structure of a transistor for display driving according to an embodiment comprises a substrate, a device layer disposed on the substrate including a plurality of transistors, and at least one insulating layer disposed on the device layer, a plurality of metal wirings that electrically connect the plurality of transistors and are spaced apart from each other and disposed in the insulating layer; and an air gap disposed between the spaced metal wirings; and an oxidation prevention layer disposed on the metal wirings.

The oxidation prevention layer may be disposed on the top and side surfaces of the metal wiring and the insulating layer.

### CROSS-REFERENCE TO RELATED APPLICATIONS

The present application claims the benefits of priority to Korean Patent Application Nos. 10-2022-0169613, filed on Dec. 7, 2022, and 10-2023-0170105, filed on Nov. 29, 2023, which are incorporated herein by reference in their entireties.

### TECHNICAL FIELD

The embodiment relates to a wiring structure of a transistor for display driving, a method of manufacturing the same and a display driver IC including the same.

### BACKGROUND

A display driver integrated circuit (DDI) for driving the display panel may be connected to the display panel.

The display driver integrated circuit uses medium voltage (MV) transistors or high voltage (HV) transistors for panel control.

Meanwhile, metal wiring is used to connect the wiring between transistors, and an oxide-based insulating layer is used to insulate the metal wiring.

However, as technology advances, the gap between metal wirings is decreasing, and transistors for medium voltage or high voltage use high voltages of about 8 V to 25 V, so there is a problem in that insulation breakdown between metal wirings may occur.

Meanwhile, due to the recent miniaturization of semiconductor processes, Fin-FET technology of 16 nm or 10 nm or less is being implemented by reducing the line width and inter-width spacing of BEOL (Back End of Line) metal wiring.

However, these ultra-fine medium-voltage or high-voltage CMOS transistors have an operating voltage (Vop) of about 8 V or more, and it is necessary to ensure the reliability of these medium-voltage or high-voltage CMOS transistors.

Accordingly, in the undisclosed internal technology, reliability can be ensured by allowing wiring to be used in a designated routing layer for the wiring that electrically connects the transistor of the DDIC.

However, if there is a restriction that the wiring is used only in the designated routing layer, there is a problem in that the DDIC chip size is unnecessarily increased due to the increase in the wiring layer.

In addition, as the insulating layer is inevitably provided in multiple layers to use wiring only in the designated routing layer like internal technology, there is an unexpected side effect in that impedance characteristics are lowered due to an increase in the dielectric layer, resulting in a delay in signal propagation.

### SUMMARY

The technical object of the present invention is to provide a wiring structure, a manufacturing method for a display driving transistor and a display driver IC that may be implemented in a compact size while ensuring reliability between the wiring of a medium-voltage or high-voltage transistor.

Additionally, one of the technical objects of the embodiment is to solve the problem of delay in signal propagation due to an increase in the insulating layer.

Solutions for solving the technical problem of the embodiments can include any one of the following.

The wiring structure of a transistor for driving a display panel according to an embodiment may include a substrate, a device layer including a plurality of transistors and disposed on the substrate, at least one insulating layer disposed on the device layer, a plurality of metal wirings that electrically connect the plurality of transistors and are spaced apart from each other and disposed on the insulating layer, an air gap disposed between the spaced apart metal wirings and an oxidation prevention layer disposed on the metal wiring.

The oxidation prevention layer may be disposed on the top and side surfaces of the metal wiring and the insulating layer.

The device layer may include a medium voltage (MV) or high voltage (HV) transistor.

The oxidation prevention layer may include a metal layer containing one or more of Ru, Co, and Mn.

The oxidation prevention layer may include Ru, Co, or Mn-based metal oxide or metal nitride.

The oxidation prevention layer may include a metal layer containing one or more of Ru, Co, and Mn disposed on the insulating layer, and a Ru, Co, Mn-based metal oxide layer or metal nitride layer disposed on the metal layer.

The embodiment may further include a bonding improvement layer disposed on the oxidation prevention layer, and the bonding improvement layer may include one or more nitrides of TaN, TiN, WN, RuTaN, or a phosphide of CoWP or NiMoP.

The insulating layer may include a first insulating layer disposed on the device layer, and a second insulating layer and a third insulating layer disposed on the oxidation prevention layer.

The metal wiring may include a first metal wiring disposed in the first insulating layer, a second metal wiring disposed in the second insulating layer, and a third metal wiring disposed in the third insulating layer.

Further, a first width of a lower side of the air gap may be larger than a second width of an upper side of the air gap. Further, a first width of a lower side of the metal wiring may be smaller than a second width of an upper side of the metal wiring.

In addition, the wiring structure of the transistor for display driving may include a substrate, a device layer including a plurality of transistors and disposed on the substrate, at least one insulating layer disposed on the device layer, a plurality of metal wirings that electrically connect the plurality of transistors and are spaced apart from each other and disposed in the insulating layer, an air gap disposed between the spaced metal wirings and an oxidation prevention layer disposed on the metal wirings.

The air gap may include a first through air gap formed by penetrating at least two of the plurality of insulating layers in a vertical direction and a second air gap formed in the one insulating layer.

The insulating layer may include a first insulating layer disposed on the device layer; and a second insulating layer and a third insulating layer disposed on the oxidation preventing layer. The first through air gap is a first-first through air gap formed by vertically penetrating the first insulating layer and the second insulating layer, and a first-second through air gap formed by penetrating the second insulating layer and the third insulating layer in a vertical direction.

The first-first through air gap and the first-second through air gap may not overlap in the vertical direction.

Further, the first-first through air gap and the first-second through air gap may overlap at least partially in a horizontal direction. Further, the second air gap may include a second-first air gap to overlap the first-first through air gap in the horizontal direction, and a second-second air gap to overlap the first-second through air gap in the horizontal direction.

Further, the second-first air gap may overlap the first-second through air gap in the vertical direction, and the second-second air gap may overlap the first-first through air gap in the vertical direction. Further, a first width of a lower side of the air gap may be larger than a second width of an upper side of the air gap. Further, a first width of a lower side of the metal wiring may be smaller than a second width of an upper side of the metal wiring.

In addition, a method of manufacturing a wiring structure of a transistor for display driving according to an embodiment may include forming a plurality of metal wirings spaced apart from each other in the first insulating layer, forming an air gap between the spaced metal wirings by removing at least a portion of the first insulating layer between the spaced metal wirings, forming an oxidation prevention layer on the top and sides of the spaced metal wiring and forming a second insulating layer on the oxidation prevention layer.

The air gap may include a first through air gap formed by penetrating the plurality of insulating layers in a vertical direction and a second air gap formed in the one insulating layer.

According to the wiring structure of the transistor for display driving according to the embodiment, there is a technical effect of enabling a compact size while ensuring reliability between the wiring of the medium voltage or high voltage transistor.

For example, according to the wiring structure of the transistor for display driving according to the embodiment, an air gap with high dielectric constant may be formed between metal wirings, so insulation reliability can be improved and unnecessary wiring layers can be reduced.

Additionally, according to the embodiment, an oxidation prevention layer can be formed on metal wiring to prevent short circuits between metal wiring.

In addition, according to the wiring structure 200 of the transistor for display driving according to the embodiment, by forming an air gap 250 between metal wirings and including an oxidation prevention layer 260 and the junction improvement layer 270, the limitation of forming a wiring layer only in a designated routing layer can be overcome, and there is a technical feature that can significantly compact the size of the DDIC chip.

In addition, according to the embodiment, an air gap 250 may be formed between metal wirings, and the oxidation prevention layer 260 and the bonding improvement layer 270 are included, thereby the limitation of forming a wiring layer only on a designated routing layer can be overcome and the problem of delay in signal propagation can be solved by preventing an increase in the insulation layer.

The technical effects of the embodiments are not limited to those described in this item and include those that can be understood through the description of the invention.

### BRIEF DESCRIPTION OF THE DRAWINGS

The accompanying drawings, which are incorporated herein and form part of the specification, illustrate various, non-limiting embodiments of the present invention. In the drawings, like reference numbers indicate identical or functionally similar elements.

FIG. 1A is an exemplary configuration diagram of a display system to which a display driving device according to an embodiment is applied.

FIG. 1B is a partial block diagram of a gate driver according to an embodiment.

FIG. 2 shows the wiring structure of a transistor for display driving according to internal technology.

FIG. 3 is a diagram showing the wiring structure of a transistor for driving a display according to an embodiment of the present invention.

FIG. 4 is a diagram showing the wiring structure of a transistor for display driving according to another embodiment of the present invention.

FIG. 5 is a process diagram of a manufacturing method of the wiring structure of a transistor for display driving according to an embodiment.

### DETAILED DESCRIPTION

Hereinafter, embodiments disclosed in the present specification will be described in detail with reference to the attached drawings, but identical or similar elements will be assigned the same reference numbers regardless of the reference numerals, and duplicate descriptions thereof will be omitted. The suffixes ‘module’ and ‘part’ for elements used in the following description are given or used interchangeably in consideration of ease of specification preparation, and do not have distinct meanings or roles in themselves. Additionally, the attached drawings are intended to facilitate easy understanding of the embodiments disclosed in this specification, and the technical idea disclosed in this specification is not limited by the attached drawings. Additionally, when an element such as a layer, region or substrate is referred to as being ‘on’ another element, this includes either directly on the other element or there may be other intermediate elements in between.

### Embodiment

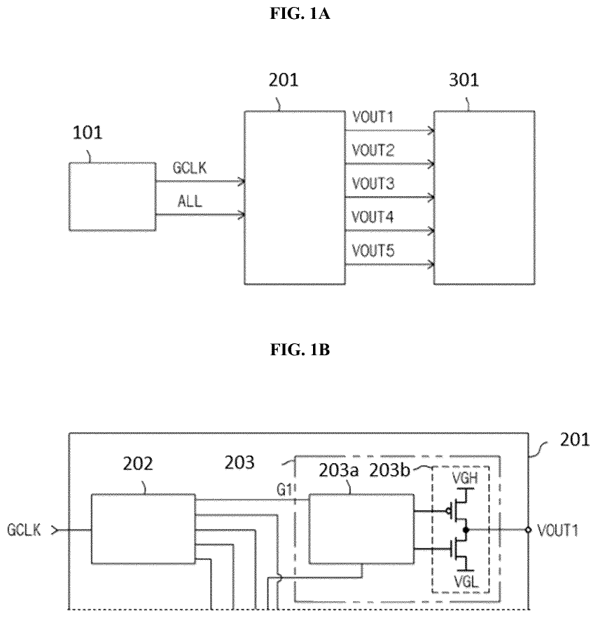

FIG. 1A is an exemplary configuration diagram of a display system to which a display driving device according to an embodiment is applied, and FIG. 1B is a partial block diagram of a gate driver according to an embodiment.

Referring to FIG. 1A, a display system to which a display driving device according to an embodiment is applied may include a timing controller 101, a gate driver 201, a source driver (not shown), and a display panel 301.

The gate driver 201 may receive the gate clock signal (GCLK) and control signal (ALL) from the timing controller 101 and provide gate driving signals (VOUT1 to VOUT5) to the display panel 301.

The timing controller 101 may provide a control signal and a gate clock signal (GCLK) to control the operation of the gate driver 201. The control signal may include, but is not limited to, a gate enable signal for enabling the operation of the gate driver 201 or a control signal (All) for a power down mode.

The display panel 301 may be a variety of flat display panels, such as a liquid crystal display panel, a light emitting diode display panel, and an organic light emitting diode display panel.

Additionally, the display system of the embodiment may include devices such as a source driver (not shown) and a power supply (not shown). The source driver provides a source driving signal corresponding to data provided from the timing controller 101 to the display panel 301. And, the power supply unit provides voltages necessary for the operation of the timing controller 101, gate driver 201, and source driver.

Next, referring to FIG. 1B, the gate driver 201 of the embodiment may include a gate signal processing unit 202, a control unit (not shown), and an output circuit 203.

The gate signal processing unit 202 may receive the gate clock signal (GCLK) provided from the timing controller 101 and may output a gate signal (G) corresponding to the gate driving signal (VOUT1) to be provided to the display panel 301.

The control unit may receive the control signal (ALL) and generate driving control signals with a time difference in activation time in response to the control signal (ALL), but is not limited thereto.

Next, each output circuit 203 may include a level shifter 203a and an output buffer 203b, and may be configured in numbers corresponding to the output channels of the gate driver 201. The output circuits 203 may respectively receive a gate signal (G) and a driving control signal (ALL), and output gate driving signals (VOUT1 to VOUT5), respectively.

At this time, the level shifter 203a may compensate for the level of the gate signal (G) in response to the inactive driving control signal (ALL1), and may provide the gate signal (G) with the compensated level to the output buffer 203b. The level shift 203a may perform an inverter operation for input, but is not limited to this.

As described above, a display driver IC according to an embodiment may use a medium voltage (MV) transistor or a high voltage (HV) transistor for panel control.

For example, the output buffer 203b of the embodiment may include a PMOS transistor and an NMOS transistor, and may have a configuration in which the drains of the PMOS transistor and the NMOS transistor are commonly connected. Accordingly, the output buffer 203b may be configured as a buffer including a CMOS transistor. And, in the output buffer 203b, a gate high voltage (VGH) may be applied to the PMOS transistor and a gate low voltage (VGL) may be applied to the NMOS transistor.

Additionally, a node where the drains of the PMOS transistor and the NMOS transistor of the output buffer 203b are commonly connected may form an output terminal that outputs the gate driving signal (VOUT1).

According to the above structure, the output buffer 203b outputs a gate high voltage (VGH) when a low-level signal is output from the level shifter 203a, and when a high level signal is output from the level shifter 203a, the gate low voltage (VGL) may be output.

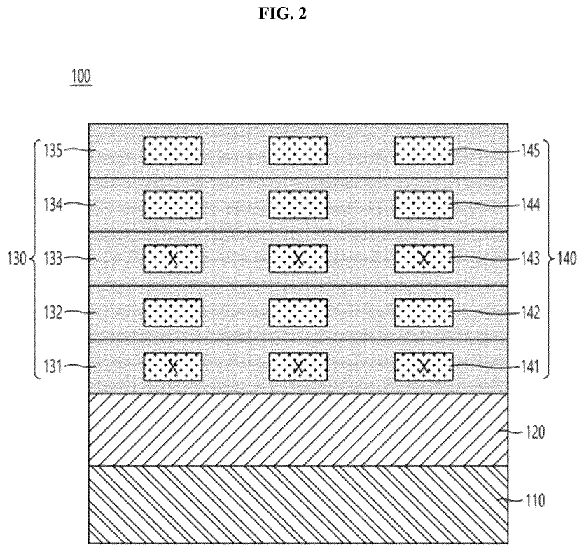

Meanwhile, FIG. 2 shows the wiring structure of a transistor for driving a display panel according to an undisclosed comparative technology.

The wiring structure 100 of a transistor according to comparative technology may include a substrate 110, a device layer 120, an insulating layer 130, and a metal wiring 140.

The substrate 110 may include a glass substrate or a silicon substrate.

The device layer 120 may include a medium voltage (MV) or high voltage (HV) transistor.

The insulating layer 130 may include a first insulating layer 131, a second insulating layer 132, a third insulating layer 133, a fourth insulating layer 134, and a fifth insulating layer 135, but is not limited to this.

The metal wiring 140 may include a first metal wiring 141 formed in the first insulating layer 131, a second metal wiring 142 formed in the second insulating layer 132, a third metal wiring 143 formed in the third insulating layer 133, a fourth metal wiring 144 formed in the fourth insulating layer 134 and a fifth metal wiring 145 formed in the fifth insulating layer 135.

Meanwhile, metal wiring is used to connect the wiring between transistors, and an oxide-based insulating layer is used to insulate the metal wiring.

For example, the insulating layer 130 may be made of an oxide-based material to insulate between the metal wirings 140.

However, as technology advances, the gap between metal wirings is decreasing, and transistors that use medium or high voltage use about 8 V to 25 V, so, there is a problem in that insulation breakdown between metal wirings may occur.

In particular, due to the recent miniaturization of semiconductor processes, Fin-FET technology of 16 nm or 10 nm or less is being implemented by reducing the line width and inter-width spacing of BEOL (Back End of Line) metal wiring.

However, these ultra-fine medium-voltage or high-voltage CMOS transistors have an operating voltage (Vop) of about 8 V or more, and in order to prevent the break down phenomenon and ensure the reliability of medium-voltage or high-voltage CMOS transistors, there is a limitation in that wiring must be used only in a designated routing layer.

For example, referring to FIG. 2, the designated routing layer among the metal wirings 140 may be the second metal wiring 142, the fourth metal wiring 144, and the fifth metal wiring 145. But, the first metal wiring 141 and the third metal wiring 143 may be an unspecified routing layer.

Accordingly, if only the wiring of the designated routing layer must be used, there is a problem in that the DDI chip size is unnecessarily increased due to the increase in the wiring layer.

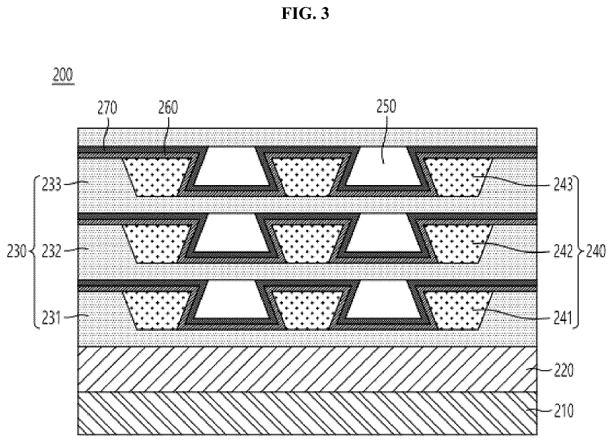

Next, FIG. 3 is a diagram showing the wiring structure 200 of a transistor for driving a display panel according to an embodiment.

The wiring structure 200 of the transistor according to the embodiment may include at least one of a substrate 210, a device layer 220, an insulating layer 230, a metal wiring 240, an air gap 250, an oxidation prevention layer 260 and a bonding improvement layer 270.

According to one embodiment, the substrate 210 may include a glass substrate or a silicon substrate.

The device layer 220 may be disposed on top of the substrate 210 and may control subpixels of the display panel.

The device layer 220 may include a medium voltage (MV) or high voltage (HV) transistor.

The insulating layer 230 may be disposed on a top surface of the device layer 220.

The insulating layer 230 may be formed of a plurality of layers. For example, the insulating layer 230 may include a first insulating layer 231, a second insulating layer 232, and a third insulating layer 233.

The metal wiring 240 may be disposed on the insulating layer 230. The metal wiring 240 may be formed in plural numbers.

For example, the metal wiring 240 may include a first metal wiring 241 disposed on the first insulating layer 231, a second metal wiring 242 disposed on the second insulating layer 232 and a third metal wiring 243 disposed on the third insulating layer 233. According to the embodiment, a first width of a lower side of the metal wiring 240 may be smaller than a second width of an upper side of the metal wiring 240.

The air gap 250 may be disposed between the metal wirings 240 to block electrical connection between the metal wirings 240. According to the embodiment, a first width of a lower side of the air gap 250 may be larger than a second width of an upper side of the air gap 250.

According to the embodiment, reliability can be secured by forming an air gap 250 with high dielectric constant between metal wirings. Accordingly, the limitation of forming a wiring layer only on a designated routing layer can be overcome, preventing an increase in the insulation layer, thereby solving the problem of delay in signal propagation.

For example, in the embodiment, by placing the air gap 250 with a high dielectric constant between the metal wirings 240, signal propagation delay can be prevented by reducing frequency dispersion due to an unnecessary increase in the insulating layer, and the signal bandwidth can be increased by expanding the impedance characteristics.

Next, the oxidation prevention layer 260 may be disposed on the metal wiring 240 to prevent the metal wiring 240 from being oxidized in a subsequent process.

The oxidation prevention layer 260 may include metal such as Ru, Co, Mn, or metal oxide or metal nitride.

Although the oxidation prevention layer 260 is made of a metal material, its resistance value can be high, so electrical connection between the metal wirings 240 may be blocked. The thickness of the oxidation prevention layer 260 may be about 20 Å, but is not limited thereto.

The oxidation prevention layer 260 may be formed of a multi-layer oxidation prevention layer. For example, the oxidation prevention layer 260 may be formed to include a first oxidation prevention layer (not shown) made of oxide or nitride and a second oxidation prevention layer (not shown) made of metal.

Next, the bonding improvement layer 270 may be disposed on the oxidation prevention layer 260, and may improve bonding between the oxidation prevention layer 260 and the insulating layer 230 disposed on the oxidation prevention layer 260.

The bonding improvement layer 270 may include nitrides such as TaN, TIN, WN, RuTaN, or phosphides such as CoWP and NiMoP.

The occurrence of cracks and void defects can be prevented by the bonding improvement layer 270.

The second insulating layer 232 may be formed on the bonding improvement layer 270.

Afterwards, the second metal wiring 242 is formed on the second insulating layer 232, and the oxidation prevention layer 260 and the bonding improvement layer 270 may be formed on the second metal wiring 242. By repeatedly performing this stacked structure, a multi-layer metal wiring structure may be formed.

According to the wiring structure 200 of the transistor according to the embodiment, since an air gap 250 may be formed between metal wirings, and by including the oxidation prevention layer 260 and the junction improvement layer 270, the limitation of forming a wiring layer only in a designated routing layer can be overcome, and there is a technical feature that can significantly compact the size of the DDI chip.

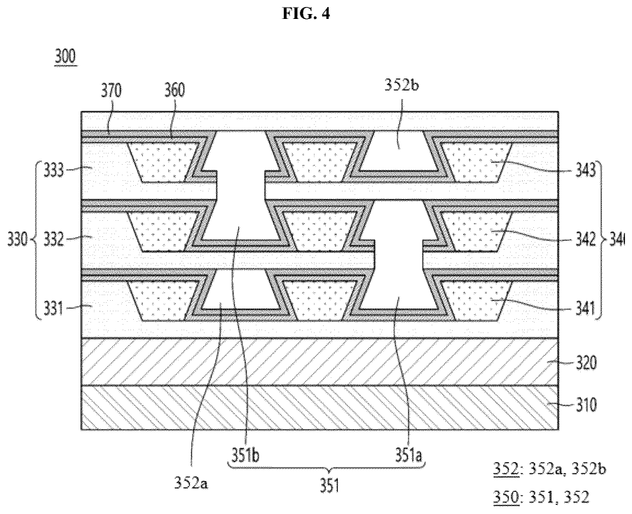

Next, FIG. 4 is a diagram showing the wiring structure 300 of a transistor according to the second embodiment.

The wiring structure of the transistor according to the second embodiment may adopt the technical features of the wiring structure 200 of the transistor according to the embodiment of FIG. 3, hereinafter, the description will focus on the main features of the second embodiment.

Referring to FIG. 4, a complex air gap 350 may be formed between the first metal wirings 341 formed in the first insulating layer 331.

The complex air gap 350 may include a first through air gap 351 penetrating the first insulating layer 331 and the second insulating layer 332, and a second air gap 352 formed only in the space of the first insulating layer 331.

It can be understood that the first through air gap 351 is formed by penetrating at least two of the plurality of insulating layers 330 in the vertical direction.

On the other hand, it can be understood that the second air gap 352 may be formed only within one of the insulating layer 330.

A first-first through air gap 351a penetrating the first insulating layer 331 and the second insulating layer 332 may not overlap a first-second through air gap 351b penetrating the second insulating layer 332 and the third insulating layer 333. In the embodiment, the first-first through air gap 351a and the first-second through air gap 351b may overlap at least partially in a horizontal direction. Further, the second air gap 352 may include a second-first air gap 352a to overlap the first-first through air gap 351a in the horizontal direction, and a second-second air gap 352b to overlap the first-second through air gap 351b in the horizontal direction. Further, the second-first air gap 352a may overlap the first-second through air gap 351b in the vertical direction, and the second-second air gap 352b may overlap the first-first through air gap 351a in the vertical direction.

In the embodiment, the first-first through air gap 351a and the first-second through air gap 351b are controlled not to overlap in the vertical direction, so that the multi-layered wiring structure can be sturdy and structural reliability can be also improved.

In FIG. 4, the description is made on the basis of having three layers of the insulating layer 330, but when the insulating layer 330 is formed of three or more layers, the first-first through air gap 351a and the first-second through air gap 351b may overlap in the vertical direction. At this time, the second air gap 352 may be arranged to overlap in the vertical direction between the first-first through air gap 351a and the first-second through air gap 351b.

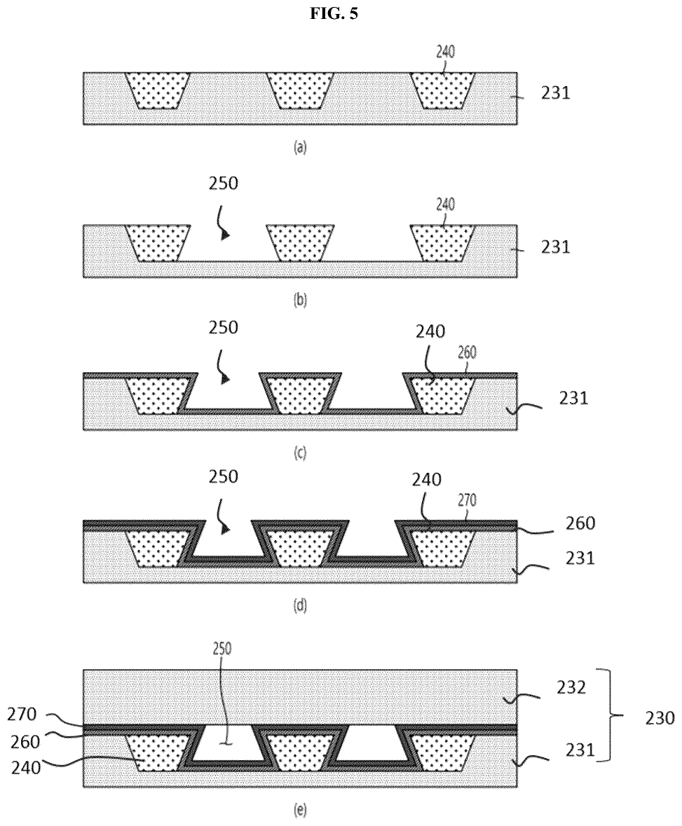

FIG. 5 shows a method of manufacturing the wiring structure 200 of a transistor according to an embodiment.

FIG. 5(a) shows the step of forming the metal wiring 240 after placing the first insulating layer 231 on the device layer 220.

The metal wiring 240 may be formed through deposition. The arrangement of the metal wiring 240 may vary depending on the wiring pattern.

FIG. 5(b) shows an etching process for forming an air gap 250 in the space between the metal wirings 240 after forming the metal wirings 240.

The first insulating layer 231 between the metal wirings 240 may be removed through etching to form a space for forming the air gap 250.

FIG. 5(c) shows a process of applying the oxidation prevention layer 260 to prevent oxidation on the first insulating layer 231 and the metal wiring 240.

The oxidation prevention layer 260 may include metal such as Ru, Co, Mn, or metal oxide or metal nitride. Even if the oxidation prevention layer 260 is made of a metal material, the resistance value of the metal material can be high, so electrical connection between the metal wirings 240 may be blocked.

FIG. 5(d) shows a process of applying the bonding improvement layer 270 on the oxidation prevention layer 260.

The bonding improvement layer 270 may include nitrides such as TaN, TIN, WN, RuTaN, or phosphides such as CoWP and NiMoP.

FIG. 5(e) shows a process of forming the second insulating layer 232 on the bonding improvement layer 270.

The adhesion between the first insulating layer 231 and the second insulating layer 232 can be improved by the bonding improvement layer 270.

Thereafter, the same process may be repeated to integrate the wiring layer in which an insulating layer 230 including the first insulating layer 231 and the second insulating layer 232, the metal wiring 240, the oxidation prevention layer 260, and the bonding improvement layer 270 are sequentially formed.

According to the wiring structure of the display driving transistor according to the embodiment, there is a technical effect of ensuring reliability between wiring of the medium-voltage or high-voltage transistor and enabling a compact size.

For example, according to the wiring structure of the transistor according to the embodiment, an air gap of high dielectric constant may be disposed between metal wirings, so insulation reliability can be improved and unnecessary wiring layers can be reduced.

Additionally, according to the embodiment, an oxidation prevention layer may be formed on the metal wirings, so short circuits between metal wirings can be prevented.

In addition, according to the wiring structure 200 of the transistor according to the embodiment, since an air gap 250 may be formed between metal wirings, and by including the oxidation prevention layer 260 and the junction improvement layer 270, the limitation of forming a wiring layer only in a designated routing layer can be overcome, and there is a technical feature that can significantly compact the size of the DDI chip.

In addition, according to the embodiment, an air gap 250 may be formed between metal wirings, and the oxidation prevention layer 260 and the bonding improvement layer 270 are included, thereby the limitation of forming a wiring layer only on a designated routing layer can be overcome and the problem of delay in signal propagation can be solved by preventing an increase in the insulation layer.

Although the above description focuses on the examples, this is only an example and does not limit the examples, those of ordinary skill in the field to which the embodiment belongs will recognize that various modifications and applications not exemplified above are possible without departing from the essential characteristics of the present embodiment. For example, each element specifically shown in the examples can be modified and implemented. And these variations and differences related to application should be interpreted as being included in the scope of the embodiments set forth in the appended claims.

What is claimed is:

1. A wiring structure of a transistor for driving a display panel, comprising:
a substrate;
a device layer including a plurality of transistors and disposed on the substrate;
at least one insulating layer disposed on the device layer;
a plurality of metal wirings that electrically connect the plurality of transistors and are spaced apart from each other and disposed on the insulating layer;
an air gap disposed between spaced apart metal wirings; and
an oxidation prevention layer disposed on the plurality of metal wirings.

2. The wiring structure according to claim 1, wherein the oxidation prevention layer is disposed on top and side surfaces of the metal wiring and the insulating layer.

3. The wiring structure according to claim 1, wherein the oxidation prevention layer comprises a metal layer including one or more of Ru, Co, and Mn, or a metal oxide or a metal nitride based on Ru, Co, and Mn.

4. The wiring structure according to claim 1, wherein the oxidation prevention layer comprises:
a metal layer including one or more of Ru, Co, and Mn disposed on the insulating layer; and
a Ru, Co or Mn-based metal oxide layer or a metal nitride layer disposed on the metal layer.

5. The wiring structure according to claim 1, further comprising:
a bonding improvement layer disposed on the oxidation prevention layer.

6. The wiring structure according to claim 1 wherein the bonding improvement layer comprises one or more nitrides of TaN, TIN, WN, RuTaN or phosphides of CoWP or NiMoP.

7. The wiring structure according to claim 1,
wherein the insulating layer comprises a first insulating layer disposed on the device layer; and
a second insulating layer and a third insulating layer disposed on the oxidation preventing layer.

8. The wiring structure according to claim 7, wherein the wiring layer comprises:
a first metal wiring disposed on the first insulating layer;
a second metal wiring disposed on the second insulating layer; and
a third metal wiring disposed on the third insulating layer.

9. The wiring structure according to claim 1, wherein a first width of a lower side of the air gap is larger than a second width of an upper side of the air gap.

10. The wiring structure according to claim 1, wherein a first width of a lower side of the metal wiring is smaller than a second width of an upper side of the metal wiring.

11. A wiring structure of a transistor for driving a display panel, comprising:
a substrate;
a device layer including a plurality of transistors and disposed on the substrate;
a plurality of insulating layers disposed on the device layer;
a plurality of metal wirings that electrically connect the plurality of transistors and are spaced apart from each other and disposed on the insulating layers;
an air gap disposed between the spaced apart metal wirings; and
an oxidation prevention layer disposed on the metal wiring,
wherein the air gap comprises a first through air gap configured to penetrate at least two of the plurality of insulating layers in a vertical direction; and a second air gap disposed in at least one of the insulating layers.

12. The wiring structure according to claim 11, wherein the insulating layers comprise a first insulating layer disposed on the device layer; and a second insulating layer and a third insulating layer disposed on the oxidation preventing layer,
wherein the first through air gap comprises:
a first-first through air gap configured to vertically penetrate the first insulating layer and the second insulating layer; and
a first-second through air gap configured to penetrate the second insulating layer and the third insulating layer in a vertical direction.

13. The wiring structure according to claim 12, wherein the first-first through air gap and the first-second through air gap do not overlap in the vertical direction.

14. The wiring structure according to claim 12, wherein the first-first through air gap and the first-second through air gap overlap at least partially in a horizontal direction.

15. The wiring structure according to claim 12, wherein the second air gap comprises a second-first air gap configured to overlap the first-first through air gap in the horizontal direction, and a second-second air gap configured to overlap the first-second through air gap in the horizontal direction.

16. The wiring structure according to claim 15, wherein the second-first air gap is configured to overlap the first-second through air gap in the vertical direction, and
the second-second air gap is configured to overlap the first-first through air gap in the vertical direction.

17. The wiring structure according to claim 11, wherein a first width of a lower side of the second air gap is larger than a second width of an upper side of the second air gap.

18. The wiring structure according to claim 11, wherein a first width of a lower side of the metal wiring is smaller than a second width of an upper side of the metal wiring.

19. A display driver IC comprising the wiring structure according to claim 1.

20. A display driver IC comprising the wiring structure according to claim 11.
